(19) United States
(12) Patent Application Publication
(10) Pub. No.: US 2015/0380268 A1
(43) Pub. Date: Dec. 31, 2015

(54) ETCHING METHOD AND STORAGE MEDIUM

(71) Applicant: TOKYO ELECTRON LIMITED, Tokyo (JP)

(72) Inventors: Satoshi TODA, Nirasaki City (JP); Nobuhiro TAKAHASHI, Nirasaki City (JP); Hiroyuki TAKAHASHI, Nirasaki City (JP)

(21) Appl. No.: 14/743,390

(22) Filed: Jun. 18, 2015

(30) Foreign Application Priority Data
Jun. 27, 2014 (JP) 2014-132482

(51) Int. Cl. H01L 21/311; G05B 19/18; H01L 21/02

(52) U.S. Cl. CPC H01L 21/31116; H01L 21/02164; H01L 21/02271; G05B 19/182; G05B 2219/45212

(57) ABSTRACT

An etching method includes: disposing a substrate to be processed within a chamber, the substrate to be processed having a silicon oxide film formed on a surface thereof and a silicon nitride film formed adjacent to the silicon oxide film; and selectively etching the silicon oxide film with respect to the silicon nitride film by supplying HF gas or HF gas and F₂ gas, an alcohol gas or water vapor, and an inert gas into the chamber.

### CROSS-REFERENCE TO RELATED APPLICATION

This application claims the benefit of Japanese Patent Application No. 2014-132482, filed on Jun. 27, 2014, in the Japan Patent Office, the disclosure of which is incorporated herein in its entirety by reference.

### TECHNICAL FIELD

The present disclosure relates to a method of etching a silicon oxide film formed on a substrate and a non-transitory storage medium.

### BACKGROUND

In recent years, in a manufacturing process of a semiconductor device, a method called chemical oxide removal (COR) which chemically performs etching within a chamber without generating plasma draws attention as a miniaturization etching technique substituted for plasma etching.

As the COR, there is known a process in which a SiO₂ film existing on a surface of a semiconductor wafer as an object to be processed is etched within a chamber held in a vacuum by causing a hydrogen fluoride (HF) gas and an ammonia (NH₃) gas to be adsorbed onto and react with the silicon oxide film (SiO₂ film) to generate ammonium fluorosilicate ((NH₄)₂SiF₆; AFS), and sublimating the ammonium fluorosilicate by heating the same in a subsequent step.

In a semiconductor wafer, there may be a case where a SiO₂ film adjoins a SiN film. In this case, it is required to etch the SiO₂ film with high selectivity with respect to the SiN film. However, in the aforementioned technique, the selectivity of the SiO₂ film to the SiN film is about 15 and is still insufficient.

### SUMMARY

Some embodiments of the present disclosure provide an etching method capable of etching a silicon oxide film with high selectivity with respect to a silicon nitride film without generating plasma within a chamber, and a non-transitory storage medium.

According to one embodiment of the present disclosure, there is provided an etching method, including: disposing a substrate to be processed within a chamber, the substrate to be processed having a silicon oxide film formed on a surface thereof and a silicon nitride film formed adjacent to the silicon oxide film; and selectively etching the silicon oxide film with respect to the silicon nitride film by supplying HF gas or HF gas and F₂ gas, an alcohol gas or water vapor, and an inert gas into the chamber.

According to another embodiment of the present disclosure, there is provided a non-transitory storage medium storing a program that operates on a computer and controls an etching apparatus, wherein the program, when executed, causes the computer to control the etching apparatus so as to perform the etching method of the embodiments.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic configuration view showing one example of a processing system including an etching apparatus that performs an etching method according to an embodiment of the present disclosure.

FIG. 2 is a sectional view showing a heat treatment apparatus equipped in the processing system shown in FIG. 1.

FIG. 3 is a sectional view showing an etching apparatus equipped in the processing system shown in FIG. 1.

FIG. 4 is a view showing a relationship between an internal pressure of a chamber and etching amounts of an ALD-SiO₂ film and a SiN film in Experimental Example 1.

FIG. 5 is a view showing a relationship between the internal pressure of the chamber and etching amounts of a thermal oxide film and the SiN film in Experimental Example 1.

FIG. 6 is a view showing a relationship between the internal pressure of the chamber and etching amounts of an ALD-SiO₂ film and a SiN film in Experimental Example 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One Example of Processing System used in Embodiments of the Present Disclosure

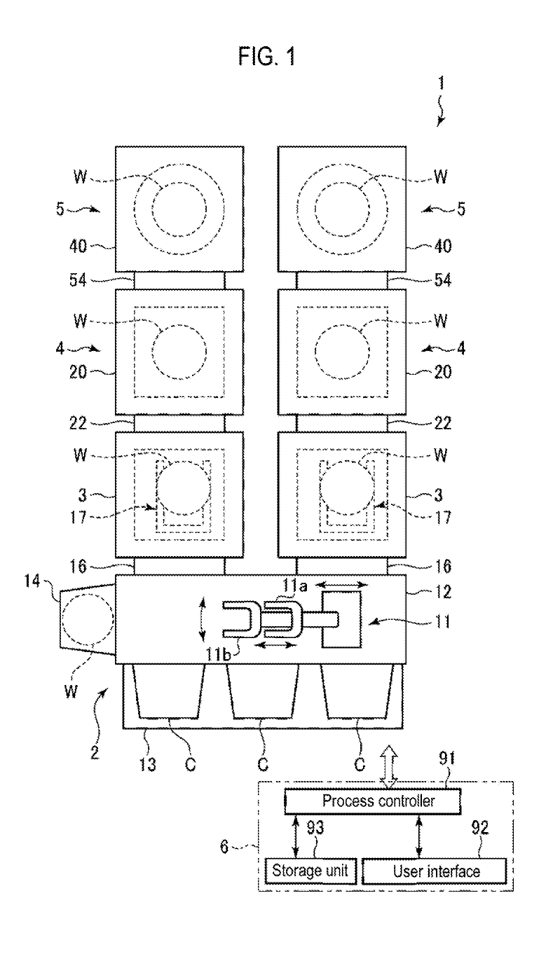

FIG. 1 is a schematic configuration view showing one example of a processing system equipped with an etching apparatus according to one embodiment of the present disclosure. The processing system 1 includes: a loading/unloading unit 2 configured to load and unload a semiconductor wafer (hereinafter simply referred to as a “wafer”) W; two load lock chambers (L/L) 3 disposed adjacent to the loading/unloading unit 2; two heat treatment apparatuses 4 disposed adjacent to the corresponding load lock chambers 3 and configured to perform a heat treatment with respect to the wafer W; two etching apparatuses 5 according to the present embodiment, which are disposed adjacent to the corresponding heat treatment apparatuses 4 and configured to perform etching with respect to the wafer W without generating plasma within a chamber; and a control unit 6.

The loading/unloading unit 2 includes a transfer chamber (L/M) 12 within which a first wafer transfer mechanism 11 for transferring the wafer W is installed. The first wafer transfer mechanism 11 includes two transfer arms 11a and 11b configured to hold the wafer W in a substantially horizontal posture. A mounting stage 13 is installed at one longitudinal side of the transfer chamber 12. The mounting stage 13 is configured to mount one or more, for example, three, carriers C capable of accommodating a plurality of wafers W, respectively. In addition, an orienter 14 configured to perform position alignment of the wafer W by rotating the wafer W and finding an eccentric amount thereof is installed adjacent to the transfer chamber 12.

In the loading/unloading unit 2, the wafer W is held by one of the transfer arms 11a and 11b and is moved linearly within a substantially horizontal plane or moved up and down by the operation of the first wafer transfer mechanism 11, thereby being transferred to a desired position. Further, the wafer W is loaded or unloaded with respect to the carriers C mounted on the mounting stage 13, the orienter 14 and the load lock chambers 3, as the transfer arms 11a and 11b move toward or away from the carriers C, the orienter 14 and the load lock chambers 3.

Each of the load lock chambers 3 is connected to the transfer chamber 12 with a gate valve 16 interposed between each of the load lock chambers 3 and the transfer chamber 12. A second wafer transfer mechanism 17 for transferring the wafer W is installed within each of the load lock chambers 3. Each of the load lock chambers 3 is configured so that it can be evacuated to a predetermined vacuum degree.

The second wafer transfer mechanism 17 has an articulated arm structure and includes a pick configured to hold the wafer W in a substantially horizontal posture. In the second wafer transfer mechanism 17, the pick is positioned within each of the load lock chambers 3 when an articulated arm is retracted. The pick can reach a corresponding heat treatment apparatus 4 as the articulated arm is extended and can reach a corresponding etching apparatus 5 as the articulated arm is further extended. Thus, the second wafer transfer mechanism 17 can transfer the wafer W between the load lock chamber 3, the heat treatment apparatus 4 and the etching apparatus 5.

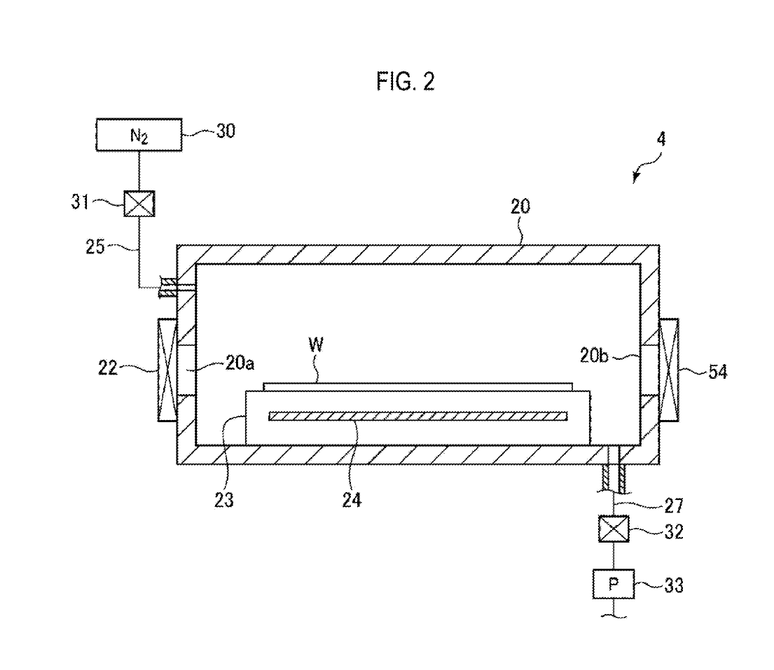

As shown in FIG. 2, each of the heat treatment apparatuses 4 includes a vacuum-evacuable chamber 20 and a mounting table 23 configured to mount the wafer W within the chamber 20. A heater 24 is embedded in the mounting table 23. After being subjected to an etching process, the wafer W is heated by the heater 24, thereby vaporizing and removing etching residue which exists on the wafer W. A loading/unloading gate 20a through which the wafer W is transferred between each of the heat treatment apparatuses 4 and corresponding load lock chambers 3 is installed in the sidewall of the chamber 20 adjoining the load lock chamber 3. The loading/unloading gate 20a is opened and closed by a gate valve 22. In addition, a loading/unloading gate 20b through which the wafer W is transferred between the heat treatment apparatus 4 and corresponding etching apparatuses 5 is installed in the sidewall of the chamber 20 adjoining the etching apparatus 5. The loading/unloading gate 20b is opened and closed by a gate valve 54. A gas supply path 25 is connected to an upper portion of the sidewall of the chamber 20. The gas supply path 25 is connected to an N₂ gas supply source 30. An exhaust path 27 is connected to the bottom wall of the chamber 20. The exhaust path 27 is connected to a vacuum pump 33. A flow rate adjusting valve 31 is installed in the gas supply path 25. A pressure adjusting valve 32 is installed in the exhaust path 27. By controlling the flow rate adjusting valve 31 and the pressure adjusting valve 32, the interior of the chamber 20 is kept in a N₂ gas atmosphere having a predetermined pressure. In this state, a heat treatment is performed. Instead of the N₂ gas, another inert gas such as an Ar gas or the like may be used.

The control unit 6 includes a process controller 91 provided with a microprocessor (computer) which controls the respective constituent parts of the processing system 1. A user interface 92, which includes a keyboard that allows an operator to perform a command input operation or the like in order to manage the processing system 1 and a display that visualizes and displays an operation status of the processing system 1, is connected to the process controller 91. Also connected to the process controller 91 is a storage unit 93 which stores: control programs for realizing, under the control of the process controller, various types of processes performed in the processing system 1, for example, supply of a process gas and evacuation of the interior of the chamber in each of the etching apparatuses 5 to be described later; process recipes which are control programs for allowing the respective constituent parts of the processing system 1 to perform specified processes according to process conditions; and various types of databases. The process recipes are stored in a suitable storage medium (not shown) of the storage unit 93. If necessary, an arbitrary recipe is called out from the storage unit 93 and is executed by the process controller 91. In this way, desired processes are performed in the processing system 1 under the control of the process controller 91.

The etching apparatuses 5 according to the present embodiment are configured to etch a SiO₂ film into a specified pattern using F₂ gas, HF gas, an alcohol gas and the like. A detailed configuration of the etching apparatuses 5 will be described later.

In the processing system 1, a wafer having a SiO₂ film as an etching target formed on the surface thereof and a SiN film formed adjacent to the SiO₂ film is used as the wafer W. A plurality of wafers W of this type is accommodated within the carriers C and is transferred to the processing system 1. In the processing system 1, one of the wafers W is transferred from the carriers C mounted in the loading/unloading unit 2 to one of the load lock chambers 3 by one of the transfer arms 11a and 11b of the first wafer transfer mechanism 11 while keeping the atmosphere-side gate valve 16 open, and is delivered to the pick of the second wafer transfer mechanism 17 disposed within the load lock chamber 3.

Thereafter, the atmosphere-side gate valve 16 is closed and the interior of the load lock chamber 3 is evacuated. Subsequently, the gate valve 54 is opened and the pick is extended into a corresponding etching apparatuses 5, so that the wafer W is transferred to the etching apparatus 5.

Thereafter, the pick is returned to the load lock chamber 3 and the gate valve 54 is closed. Then, an etching process is performed within the etching apparatus 5 in the below-described manner.

After the etching process is completed, the gate valves 22 and 54 are opened. The etched wafer W is transferred to the heat treatment apparatus 4 by the pick of the second wafer transfer mechanism 17. While introducing N₂ gas into the chamber 20, the wafer W mounted on the mounting table 23 is heated by the heater 24, thereby thermally removing etching residue or the like.

After the heat treatment is completed in the heat treatment apparatus 4, the gate valve 22 is opened. The etched wafer W mounted on the mounting table 23 is moved to the load lock chamber 3 by the pick of the second wafer transfer mechanism 17. Then, the etched wafer W is returned to one of the carriers C by one of the transfer arms 11a and 11b of the first wafer transfer mechanism 11. Thus, a process for one wafer is completed.

In the present embodiment, since a reaction product to be removed by the COR in the related art is not generated in the etching apparatuses 5, the heat treatment apparatuses 4 are not essential. In cases where no heat treatment apparatus is used, the wafer W after the etching process may be moved to one of the load lock chambers 3 by the pick of the second wafer transfer mechanism 17 and then returned to one of the carriers C by one of the transfer arms 11a and 11b of the first wafer transfer mechanism 11.

### Configuration of Etching Apparatus

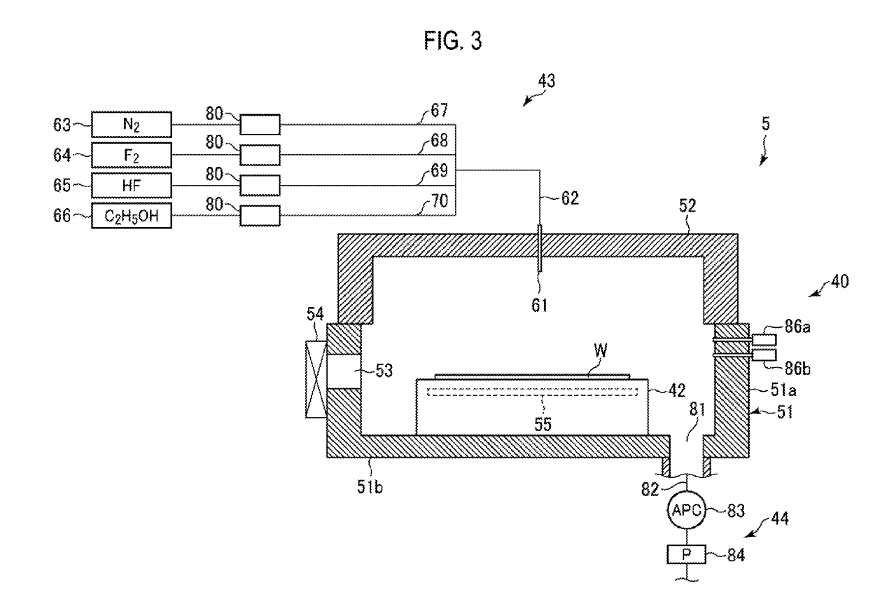

Next, the etching apparatus 5 according to the present embodiment will be described in detail. FIG. 3 is a sectional view showing the etching apparatus according to the present embodiment. As shown in FIG. 3, the etching apparatus 5 includes a chamber 40 having a sealed structure. A mounting table 42 configured to mount the wafer W in a substantially horizontal posture is installed within the chamber 40. The etching apparatus 5 further includes a gas supply mechanism 43 configured to supply an etching gas to the chamber 40 and an evacuation mechanism 44 configured to evacuate the interior of the chamber 40.

The chamber 40 is configured by a chamber body 51 and a cover portion 52. The chamber body 51 includes a substantially cylindrical sidewall portion 51a and a bottom portion 51b. The upper portion of the chamber body 51 is opened. This opening is closed by the cover portion 52. The sidewall portion 51a and the cover portion 52 are sealed by a seal member (not shown), thereby securing the air-tightness of the interior of the chamber 40. A gas introduction nozzle 61 is inserted through the ceiling wall of the cover portion 52 so as to extend from above toward the interior of the chamber 40.

A loading/unloading gate 53 through which the wafer W is loaded and unloaded between the chamber 40 of the etching apparatus 5 and the chamber 20 of the heat treatment apparatus 4 is installed in the sidewall portion 51a. The loading/unloading gate 53 is opened and closed by a gate valve 54.

The mounting table 42 has a substantially circular shape when viewed from the top, and is fixed to the bottom portion 51b of the chamber 40. A temperature controller 55 configured to control the temperature of the mounting table 42 is installed within the mounting table 42. The temperature controller 55 includes a pipe line through which a temperature control medium (e.g., water, etc.) circulates. By heat exchange between the mounting table 42 and the temperature control medium flowing through the pipe line, the temperature of the mounting table 42 is controlled and hence the temperature of the wafer W mounted on the mounting table 42 is controlled.

The gas supply mechanism 43 includes a N₂ gas supply source 63 which supplies N₂ gas as an inert gas, a F₂ gas supply source 64 which supplies F₂ gas, a HF gas supply source 65 which supplies HF gas, and an ethanol gas supply source 66 which supplies ethanol (C₂H₅OH) gas as an alcohol gas. The gas supply mechanism 43 further includes a first gas supply pipe 67 connected to the N₂ gas supply source 63, a second gas supply pipe 68 connected to the F₂ gas supply source 64, a third gas supply pipe 69 connected to the HF gas supply source 65, a fourth gas supply pipe 70 connected to the ethanol gas supply source 66, and a common gas supply pipe 62 to which the first to fourth gas supply pipes 67 to 70 are connected. The common gas supply pipe 62 is connected to the gas introduction nozzle 61 mentioned above.

Flow rate controllers 80 configured to perform a flow path opening/closing operation and a flow rate control operation are installed in the first to fourth gas supply pipes 67 to 70. Each of the flow rate controllers 80 is configured by, e.g., an opening/closing valve and a mass flow controller.

Since F₂ gas is a gas having an extremely high activity rate, a gas cylinder ordinarily used as the F₂ gas supply source 64 contains F₂ gas diluted with an inert gas, typically an inert gas such as N₂ gas or Ar gas, at a volume ratio of F2 gas to the inert gas equal to 1:4. F₂ gas may be diluted with inert gases other than N₂ gas or Ar gas.

In the gas supply mechanism 43 configured as above, the N₂ gas, F₂ gas, HF gas and ethanol gas are supplied from the N₂ gas supply source 63, the F₂ gas supply source 64, the HF gas supply source 65 and the ethanol gas supply source 66 to the common gas supply pipe 62 through the first to fourth gas supply pipes 67 to 70, respectively, and then are supplied into the chamber 40 via the gas introduction nozzle 61. A shower plate may be installed in the upper portion of the chamber 40 to supply the aforementioned gases in a shower-like manner through the shower plate.

In the present embodiment, although ethanol gas is used as an example of the alcohol gas, alcohol is not limited to ethanol but may be other types of alcohol. In that case, a gas supply source configured to supply the relevant alcohol gas may be used in place of the ethanol gas supply source 66. In some embodiments, a monovalent alcohol may be used as the alcohol. In addition to ethanol, at least one of methanol (CH₃OH), propanol (C₃H₇OH), and butanol (C₄H₉OH) may be suitably used as the monovalent alcohol. Propanol has two types of structural isomers and butanol has four types of structural isomers, whichever may be used as the monovalent alcohol. It is presumed that an OH group contained in alcohol contributes to etching. Instead of alcohol, water may be used as an OH group containing material. In that case, water vapor may be supplied from a water vapor supply source instead of the ethanol gas supply source 66.

N₂ gas as an inert gas is used as a dilution gas. Alternatively, Ar gas or both N₂ gas and Ar gas may be used as the inert gas. Although N₂ gas and Ar gas may be used as the inert gas in some embodiments, other inert gases, e.g., rare gases other than Ar gas such as He gas and the like, may be used in some other embodiments. The inert gas may be used not only as the dilution gas but also as a purge gas that purges the interior of the chamber 40.

The evacuation mechanism 44 includes an exhaust pipe 82 connected to an exhaust port 81 formed in the bottom portion 51b of the chamber 40. The evacuation mechanism 44 further includes an automatic pressure control valve (APC) 83, which is installed in the exhaust pipe 82 and configured to control the internal pressure of the chamber 40, and a vacuum pump 84 configured to evacuate the interior of the chamber 40.

In the sidewall of the chamber 40, two capacitance manometers 86a and 86b as pressure gauges for measuring the internal pressure of the chamber 40 are installed such that the capacitance manometers 86a and 86b are inserted into the chamber 40. The capacitance manometer 86a is used to measure a high pressure while the capacitance manometer 86b is used to measure a low pressure. A temperature sensor (not shown) for detecting the temperature of the wafer W is installed near the wafer W mounted on the mounting table 42.

Aluminum is used as the material of the respective constituent parts, such as the chamber 40 and the mounting table 42, which constitute the etching apparatus 5. The aluminum material which constitutes the chamber 40 may be a pure aluminum material or an aluminum material having an anodized inner surface (the inner surface of the chamber body 51, etc.). On the other hand, the surface of the aluminum material which constitutes the mounting table 42 requires wear resistance. Therefore, an oxide film (Al₂O₃ film) having high wear resistance may be in some embodiments formed on the surface of the aluminum material by anodizing the aluminum material.

### Etching Method using Etching Apparatus

Next, a description will be made on an etching method using the etching apparatus configured as above.

In this example, while keeping the gate valve 54 open, the wafer W having the aforementioned configuration, i.e., the wafer W having a SiO₂ film as an etching target formed on the surface thereof and a SiN film formed adjacent to the SiO₂ film, is loaded from the loading/unloading gate 53 into the chamber 40 by the pick of the second wafer transfer mechanism 17 disposed within the load lock chamber 3. Then, the wafer W is mounted on the mounting table 42. The SiO₂ film as the etching target may be either a thermal oxide film or a film formed by a chemical vapor deposition (CVD) method or an atomic layer deposition (ALD) method. Examples of the SiO₂ film formed by the CVD method or the ALD method include a film formed by using SiH₄ or aminosilane as a Si precursor. In addition, examples of the SiN film include a film formed by the CVD method or the ALD using dichlorosilane (DCS; SiCl₂H₂), hexachlorodisilane (HCD; Si₂Cl₆), and the like as a Si precursor.

Thereafter, the pick is returned to the load lock chamber 3. The gate valve 54 is closed to keep the interior of the chamber 40 in a sealed state.

Subsequently, F₂ gas, HF gas and ethanol gas as an alcohol gas are diluted with N₂ gas as an inert gas and are introduced into the chamber 40, thereby selectively etching the SiO₂ film in the wafer W.

Specifically, the temperature of the mounting table 42 is controlled by the temperature controller 55 so as to fall within a predetermined range. The internal temperature of the chamber 40 is also regulated to fall within a predetermined range. In this state, N₂ gas, F₂ gas, HF gas and ethanol gas are introduced from the N₂ gas supply source 63, the F₂ gas supply source 64, the HF gas supply source 65 and the ethanol gas supply source 66 of the gas supply mechanism 43 into the chamber 40 through the first to fourth gas supply pipes 67 to 70, the common gas supply pipe 62 and the gas introduction nozzle 61, thereby etching the SiO₂ film.

At this time, F₂ gas is not essential, and only HF gas may be supplied instead of supplying both HF gas and F₂ gas. As described above, other alcohol gases may be used in place of ethanol gas, monovalent alcohol may be used in some embodiments as the alcohol, and besides ethanol, methanol, propanol or butanol may be suitably used as the monovalent alcohol. In addition, water vapor may be used in place of the alcohol gas.

Thus, combination of F₂ gas, HF gas and ethanol gas or combination of HF gas and ethanol gas is suitably diluted by N₂ gas as an inert gas. Therefore, the SiO₂ film can be etched with high selectivity with respect to the SiN film and with high etching rate without stopping the etching.

In some embodiments, the etching process may be performed under a high-temperature and high-pressure condition. This is because, under a high temperature and a high pressure, adsorption probability of gases increases to promote the etching. Specifically, in some embodiments, the internal pressure of the chamber 40 may fall within a range from 1,300 to 40,000 Pa (from about 10 to 300 Torr) and the temperature of the mounting table 42 (approximately, the temperature of the wafer W) may range from 100 to 300 degrees C. In some other embodiments, the internal pressure of the chamber 40 may range from 3,900 to 13,000 Pa (from about 30 to 100 Torr) and the temperature of the mounting table 42 may range from 150 to 250 degrees C.

A volume ratio (flow rate ratio) of F₂ gas to the total sum of F₂ gas+HF gas may fall within a range from 0 to 85 volume % in some embodiments, and may fall within a range of from 0 to 67 volume % in some other embodiments. The alcohol gas tends to increase the etching selectivity of the SiO₂ film with respect to the SiN film. Thus, a volume ratio (flow rate ratio) of the alcohol gas to the total sum of F₂ gas+HF gas+alcohol gas may fall within a range from 10 to 85 volume % in some embodiments, and may fall within a range from 17 to 67 volume % in some other embodiments.

As described above, by using F₂ gas and HF gas or HF gas alone and also using the alcohol gas and the inert gas to optimize conditions such as the gas composition, the pressure, the temperature and the like, the SiO₂ film can be etched with extremely high etching selectivity of about 50 or higher, furthermore 100, with respect to the SiN film. Moreover, a high value of 10 nm/min or more can be obtained as the etching rate of the SiO₂ film. Particularly, if the SiO₂ film is a film formed by the CVD method or the ALD method, an extremely superior etching property can be obtained, i.e., an etching selectivity of 200 or higher with respect to the SiN film and an etching rate of 200 nm/min.

After the etching process in the etching apparatus 5 is completed in this way, the gate valve 54 is opened. The etched wafer W mounted on the mounting table 42 is unloaded from the chamber 40 by the pick of the second wafer transfer mechanism 17. Consequently, the etching process performed by the etching apparatus 5 comes to an end.

### Experimental Examples

Next, a description will be made on experimental examples.

### [Experimental Example 1]

In Experimental Example 1, a wafer to which a chip having a thermal oxide film and an ALD-SiO₂ film formed thereon is attached and a wafer to which a chip having a SiN film formed thereon were prepared. The wafers thus prepared were etched at a HF gas flow rate of 1,000 sccm, a F₂ gas flow rate (an equivalent value) of 200 sccm (an Ar gas flow rate of 800 sccm), a N₂ gas flow rate of 200 sccm, an ethanol gas flow rate of 500 sccm, a mounting table temperature of 200 degrees C., and chamber internal pressures of 30 Torr (4,000 Pa) and 50 Torr (6,665 Pa). The ALD-SiO₂ film was formed by using aminosilane as a Si precursor and the SiN film was formed by using HCD as a Si precursor.

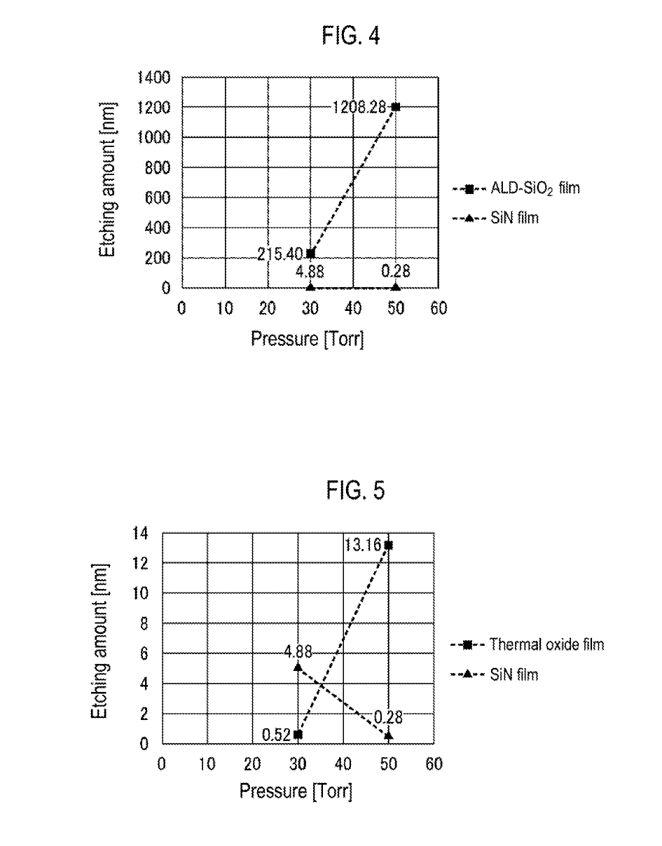

The results are shown in FIGS. 4 and 5. FIG. 4 is a view showing the relationship between the internal pressure of the chamber and the etching amounts of the ALD-SiO₂ film and the SiN film. FIG. 5 is a view showing the relationship between the internal pressure of the chamber and the etching amounts of the thermal oxide film and the SiN film. As shown in FIGS. 4 and 5, the etching selectivity of the SiO₂ film with respect to the SiN film is high at a pressure of 50 Torr (6,665 Pa). Specifically, in the thermal oxide film, a high etching selectivity of 47 was obtained, and in the ALD-SiO₂ film, a high etching selectivity of 4315.29 was obtained. In the ALD-SiO₂ film, a high etching selectivity of 44.13 was obtained even at the pressure of 30 Torr (4,000 Pa).

### [Experimental Example 2]

In Experimental Example 2, a blanket wafer having an ALD-SiO₂ film formed thereon and a blanket wafer having a SiN film formed thereon were prepared and were etched under the same conditions as those in Experimental Example 1.

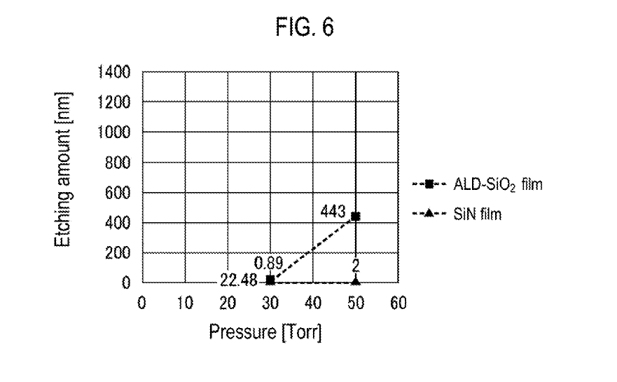

The results are shown in FIG. 6. FIG. 6 is a view showing the relationship between the internal pressure of the chamber and the etching amounts of the ALD-SiO₂ film and the SiN film. As shown in FIG. 6, a high etching selectivity of 221.50 was obtained at a pressure of 50 Torr (6,665 Pa).

### Other Applications of the Present Disclosure

The present disclosure is not limited to the aforementioned embodiments and may be differently modified. For example, the apparatuses of the aforementioned embodiments have been presented by way of example only. Indeed, the etching method according to the present disclosure may be implemented by apparatuses having different configurations. Furthermore, while there has been illustrated a case where the semiconductor wafer is used as a substrate to be processed, the substrate to be processed is not limited to the semiconductor wafer. The substrate to be processed may be other substrates such as a flat panel display (FPD) substrate represented by a liquid crystal display (LCD) substrate, a ceramic substrate, and the like.

According to the present disclosure, by supplying HF gas only or HF gas and F₂ gas, an alcohol gas or water vapor, and an inert gas into a chamber, it possible to etch, without generating plasma within the chamber, a SiO₂ film existing on a surface of a substrate to be processed with extremely high selectivity with respect to a SiN film formed adjacent to the SiO₂ film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method, comprising:
disposing a substrate to be processed within a chamber, the substrate to be processed having a silicon oxide film formed on a surface thereof and a silicon nitride film formed adjacent to the silicon oxide film; and
selectively etching the silicon oxide film with respect to the silicon nitride film by supplying HF gas or HF gas and F₂ gas, an alcohol gas or water vapor, and an inert gas into the chamber.

2. The etching method of claim 1, wherein, during the etching, an internal pressure of the chamber is set to fall within a range from 1,300 to 40,000 Pa and a temperature of a mounting table that mounts the substrate to be processed within the chamber is set to fall within a range from 100 to 300 degrees C.

3. The etching method of claim 1, wherein the alcohol gas includes at least one selected from a group consisting of ethanol (C₂H₅OH), methanol (CH₃OH), propanol (C₃H₇OH) and butanol (C₄H₉OH).

4. The etching method of claim 1, wherein, during the etching, a volume ratio of F₂ gas to a total sum of F₂ gas and HF gas is set to fall within a range from 0 to 85 volume %.

5. The etching method of claim 1, wherein, during the etching, a volume ratio of the alcohol gas to a total sum of F₂ gas, HF gas and the alcohol gas is set to fall within a range from 10 to 85 volume %.

6. The etching method of claim 1, wherein the silicon oxide film is a thermal oxide film or a film formed by a chemical deposition method or an atomic layer deposition method.

7. A non-transitory storage medium storing a program that operates on a computer and controls an etching apparatus,
wherein the program, when executed, causes the computer to control the etching apparatus so as to perform the etching method of claim 1.
